(19) United States
(12) Patent Application Publication
(10) Pub. No.: US 2024/0339969 A1
(43) Pub. Date: Oct. 10, 2024

(54) POWER AMPLIFIER CIRCUIT AND POWER AMPLIFIER MODULE

(71) Applicant: Murata Manufacturing Co., Ltd., Kyoto (JP)

(72) Inventor: Kiichiro TAKENAKA, Kyoto (JP)

(21) Appl. No.: 18/750,079

(22) Filed: Jun. 21, 2024

Related U.S. Application Data
(63) Continuation of application No. PCT/JP2022/044988, filed on Dec. 6, 2022.

(30) Foreign Application Priority Data
Dec. 28, 2021 (JP) 2021-214994

(51) Int. Cl. H03F 3/21; H03F 1/56; H03F 3/213

(52) U.S. Cl. CPC H03F 3/211; H03F 1/56; H03F 3/213; H03F 2200/387; H03F 2200/451

(57) ABSTRACT

A power amplifier circuit includes: a first power splitter that splits an input signal into a first input signal and a second input signal; an amplifier circuit that includes a pair of amplifiers electrically connected in parallel and that amplifies the first input signal and outputs an output signal to an output terminal; a control amplifier that amplifies the second input signal and outputs, to the amplifier circuit, a control signal for controlling load impedance of the amplifier circuit; and a first impedance matching unit that is electrically connected in series between the amplifier circuit and the control amplifier and includes a transmission line transformer.

### CROSS REFERENCE TO RELATED APPLICATION

This is a continuation of International Application No. PCT/JP2022/044988 filed on Dec. 6, 2022 which claims priority from Japanese Patent Application No. 2021-214994 filed on Dec. 28, 2021. The contents of these applications are incorporated herein by reference in their entireties.

### BACKGROUND ART

### Technical Field

The present disclosure relates to a power amplifier circuit and a power amplifier module.

A load modulated balanced amplifier (LMBA) is known that includes a main amplifier including a pair of amplifiers and a control amplifier that controls load impedance of the main amplifier (for example, Patent Document 1).

Patent Document 1: U.S. Pat. No. 10,404,224

### BRIEF SUMMARY

The LMBA described in Patent Document 1 has a configuration based on a 50 Ω termination for base stations. This LMBA has no impedance matching circuit provided therein since it is based on 50 Ω termination. However, in this configuration, there is a large difference in maximum output voltage between the main amplifier and the control amplifier at a coupler end where an output signal of the main amplifier and an output signal of the control amplifier are combined (see FIG. 10). Therefore, in order to improve the output efficiency in this LMBA, an impedance matching circuit needs to be provided between the control amplifier and the main amplifier to raise the output voltage of the control amplifier. However, providing such an impedance matching circuit in the LMBA causes a problem that the band of the LMBA becomes narrow.

The present disclosure provides a power amplifier circuit having characteristics capable of widening the band and improving the output efficiency.

A power amplifier circuit according to one aspect of the present disclosure includes: a first power splitter that splits an input signal into a first input signal and a second input signal; an amplifier circuit that includes a pair of amplifiers electrically connected in parallel and that amplifies the first input signal and outputs an output signal to an output terminal; a control amplifier that amplifies the second input signal and outputs, to the amplifier circuit, a control signal for controlling load impedance of the amplifier circuit; and a first impedance matching unit that is electrically connected in series between the amplifier circuit and the control amplifier and includes a transmission line transformer.

The present disclosure can provide a power amplifier circuit having characteristics capable of widening a band and improving output efficiency.

### BRIEF DESCRIPTION OF THE DRAWINGS

FIG. 1 is a diagram showing a configuration example of a power amplifier module.

FIG. 2 is a diagram showing an example of a structure of a parallel plate coupler that is a combiner.

FIG. 3 is a diagram showing an example of a structure of a λ/4 line coupler that is a combiner.

FIG. 4 is a diagram showing an example of a structure of a branch line coupler that is a combiner.

FIG. 5 is a diagram showing an example of a structure of a lumped coupler that is a combiner.

FIG. 6 is a diagram showing an example of a configuration of a communication device including the power amplifier module.

FIG. 7 is a diagram showing an example of a current

inputted to a combiner.

FIG. 8 is a graph showing an example of the

relationship between input power and efficiency of a power amplifier module according to a modification.

FIG. 9 is a graph showing an example of the relationship between input power and efficiency of a power amplifier module according to a modification.

FIG. 10 is a graph showing an example of the relationship between input power and output power of the LMBA according to Patent Document 1.

FIG. 11 is a diagram showing an example of a configuration of a power amplifier module according to a comparative example.

FIG. 12 is a diagram showing a configuration example of a power amplifier module according to a second modification.

FIG. 13 is a graph showing frequency characteristics of a parallel plate coupler.

FIG. 14 is a graph showing the relationship between a phase of a signal inputted to a control amplifier and a phase of a signal inputted to a second amplifier in the power amplifier module according to the second modification.

FIG. 15 is a diagram showing a modification of the power amplifier module according to the second modification.

FIG. 16 is a diagram showing a configuration example of a power amplifier module according to a third modification.

FIG. 17 is a graph showing the relationship between a phase of a signal outputted from a control amplifier and a phase of a signal outputted from a second amplifier in a combiner according to the third modification.

### DETAILED DESCRIPTION

Hereinafter, embodiments of the present disclosure will be described with reference to the drawings. Here, circuit elements having the same reference numerals denote the same circuit elements, and redundant description will be omitted.

### Configuration of Power Amplifier Module 100 According to This Embodiment

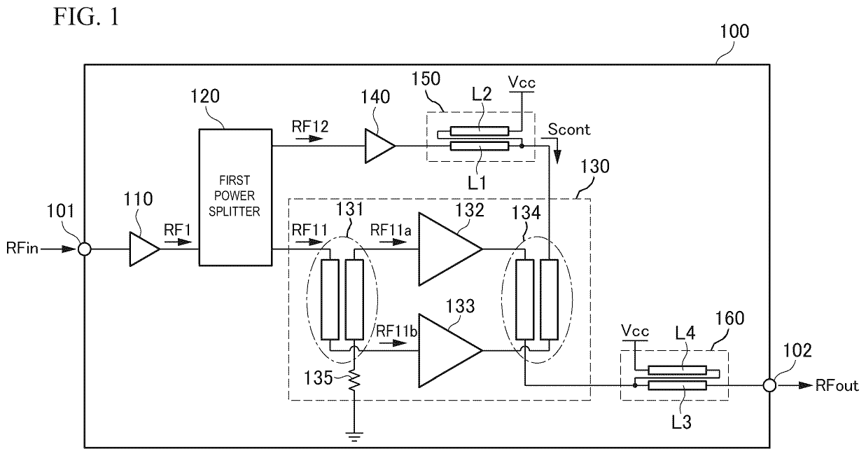

With reference to FIG. 1, a configuration of a power amplifier module 100 will be described. FIG. 1 is a diagram showing an outline of the configuration of the power amplifier module 100. The power amplifier module 100 is mounted on a mobile communication device such as a mobile phone, for example. The power amplifier module 100 amplifies the power of an input signal RFin to a level required for its transmission to a base station or a terminal, and outputs an amplified signal RFout. The input signal RFin is a radio frequency (RF) signal that is modulated according to a predetermined communication method using a radio frequency integrated circuit (RFIC), for example. Examples of the communications standards for the input signal RFin include 2G (second generation mobile communication system), 3G (third generation mobile communication system), 4G (fourth generation mobile communication system), 5G (fifth generation mobile communication system), long term evolution frequency division duplex (LTE-FDD), LTE time division duplex (LTE-TDD), LTE-Advanced, LTE-Advanced Pro or the like, and the frequency is, for example, about several hundred MHz to several tens of GHz. Note that the communications standards and frequency for the input signal RFin are not limited thereto.

The power amplifier module 100 includes, for example, a drive amplifier 110, a first power splitter 120, a balanced amplifier circuit 130, a control amplifier 140, an impedance matching unit 150, and an impedance matching unit 160.

The components of the power amplifier module 100 will be described below.

The drive amplifier 110 amplifies an input radio frequency RF signal (hereinafter referred to as an “input signal RFin”), for example, and outputs an amplified signal (hereinafter referred to as a “signal RF1”). The signal RFin has a frequency of about several GHz, for example. The drive amplifier 110 includes, but not particularly limited to, a bipolar transistor such as a heterojunction bipolar transistor (HBT), or a transistor such as a Metal Oxide Semiconductor field effect transistor (MOSFET). Note that a first amplifier 132, a second amplifier 133, and the control amplifier 140, which will be described later, have the same configuration.

The first power splitter 120 splits the signal RF1 outputted from the drive amplifier 110, for example, into a signal to be outputted to the balanced amplifier circuit 130 (hereinafter referred to as a “signal RF11”) and a signal to be outputted to the control amplifier 140 (hereinafter referred to as a “signal RF12”). The first power splitter 120 may have a function to adjust at least one of the amplitude and phase of current in the signal RF12, based on the characteristics (for example, frequency, amplitude, phase, and the like) of the signal RF1, for example. The first power splitter 120 may include, for example, a distributed constant circuit such as a coupled line 3 dB coupler or a Wilkinson power splitter. Note that the first power splitter 120 may have separate components to realize a function to split the signal RF1, a function to adjust the amplitude of the signal RF12, and a function to adjust the phase of the signal RF12, respectively. The control amplifier 140 to be described later may be configured to realize the function to adjust the amplitude of the signal RF12 and the function to adjust the phase of the current.

The balanced amplifier circuit 130 includes, for example, a second power splitter 131, the first amplifier 132, the second amplifier 133, and a combiner 134.

The second power splitter 131 splits the signal RF11 split by the first power splitter 120, for example, into a signal RF11a to be inputted to the first amplifier 132 and a signal RF11b to be inputted to the second amplifier 133. Here, the phase of the signal RF11a may be delayed by approximately 90 degrees from the phase of the signal RF11b. The phrase “approximately 90 degrees” includes, for example, a range between +45 degrees and −45 degrees centered on 90 degrees. The second power splitter 131 may be, for example, a distributed constant circuit, such as a parallel plate coupler, a λ/4 line coupler, a coupled line 3 dB coupler, a branch line coupler, or a Wilkinson power splitter. The second power splitter 131 is electrically connected to a reference potential through a resistor 135, for example.

The first amplifier 132 is, for example, an amplifier that amplifies the input signal RF11a and outputs an amplified signal. The first amplifier 132 is biased to class AB, for example. Specifically, the first amplifier 132 amplifies an input signal and outputs an amplified signal, regardless of the power level of the input signal, such as small instantaneous input power.

The second amplifier 133 is, for example, an amplifier that amplifies the input signal RF11b and outputs an amplified signal. The second amplifier 133 is, for example, an amplifier biased to the same operating point class as the first amplifier 132, here biased to class AB.

The combiner 134 combines the amplified signal outputted from the first amplifier 132 and the amplified signal outputted from the second amplifier 133, for example, to output an output signal RFout. The combiner 134 has characteristic impedance that is approximately equal to load impedance of the first amplifier 132 and the second amplifier 133, for example. The load impedance refers to the impedance when looking at the load side (output terminal 102 side) from the balanced amplifier circuit 130. The combiner 134 may be, for example, a parallel plate coupler, a λ/4 line coupler, a coupled line 3 dB coupler, or a branch line coupler. Specifically, in the power amplifier module 100, using the combiner 134 having a low characteristic impedance can omit impedance matching circuits for the first amplifier 132 and the second amplifier 133, leading to reduction in size.

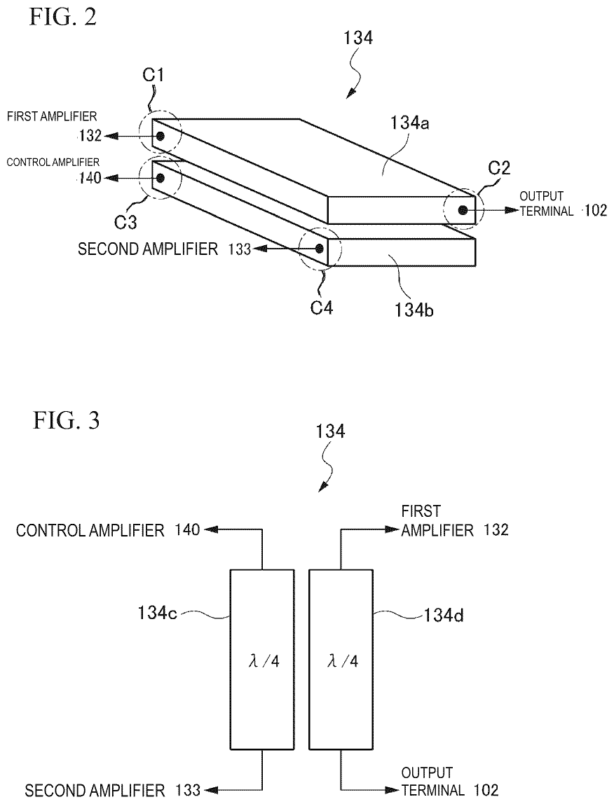

A parallel plate coupler will be described with reference to FIG. 2. FIG. 2 is a diagram showing an example of a structure of a parallel plate coupler that is the combiner 134. As shown in FIG. 2, the parallel plate coupler includes one flat plate 134a and the other flat plate 134b facing parallel to the flat plate 134a. An output terminal of the first amplifier 132 is electrically connected to one corner C1 of the flat plate 134a. The output terminal 102 is electrically connected through an impedance matching unit 160, for example, to a corner C2 opposing the one corner C1 of the flat plate 134a. The control amplifier 140 is also connected to a corner C3 of the other flat plate 134b that overlaps the one corner C1 of the flat plate 134a in the overlapping direction. An output terminal of the second amplifier 133 is electrically connected to a corner C4 of the flat plate 134b opposite to the corner C3 to which the control amplifier 140 is connected. Using such a parallel plate coupler as the combiner 134 reduces the size of the power amplifier module 100.

With reference to FIG. 3, a λ/4 line coupler will be described. FIG. 3 is a diagram showing an example of a structure of a λ/4 line coupler that is the combiner 134. As shown in FIG. 3, the λ/4 line coupler is formed of a pair of λ/4 lines that are electromagnetically coupled. One λ/4 line 134c has one end electrically connected to the output terminal of the control amplifier 140 and the other end connected to the output terminal of the second amplifier 133. The other λ/4 line 134d has one end electrically connected to the output terminal of the first amplifier 132 and the other end electrically connected to the output terminal 102 through the impedance matching unit 160, for example. Using such a λ/4 line coupler as the combiner 134 can maintain low impedance across a wide band.

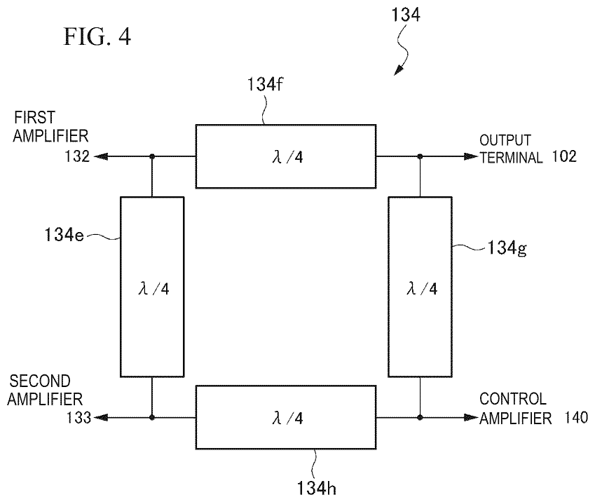

With reference to FIG. 4, a branch line coupler will be described. FIG. 4 is a diagram showing an example of a structure of a branch line coupler that is the combiner 134. As shown in FIG. 4, the branch line coupler is formed by arranging and coupling λ/4 lines 134e to 134h symmetrically in the vertical and horizontal directions. A coupling point between the λ/4 line 134e and the λ/4 line 134f is electrically connected to the output terminal of the first amplifier 132. A coupling point between the λ/4 line 134f and the λ/4 line 134g is electrically connected to the output terminal 102 through the impedance matching unit 160, for example. A coupling point between the λ/4 line 134g and the λ/4 line 134h is electrically connected to the output terminal of the control amplifier 140. A coupling point between the λ/4 line 134h and the λ/4 line 134e is electrically connected to the output terminal of the second amplifier 133. Using such a branch line coupler as the combiner 134 can maintain low impedance at high frequencies such as millimeter waves.

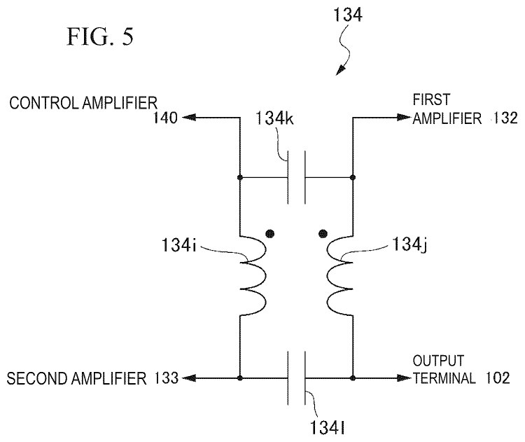

With reference to FIG. 5, a lumped coupler will be described. FIG. 5 is a diagram showing an example of a structure of a lumped coupler that is the combiner 134. As shown in FIG. 5, the lumped coupler includes a pair of magnetically coupled inductors 134i and 134j; a capacitor 134k connecting one ends of the pair of inductors 134i and 134j; and a capacitor 1341 connecting the other ends thereof. One end of the inductor 134i is electrically connected to the output terminal of the control amplifier 140. One end of the inductor 134j is electrically connected to the output terminal of the first amplifier 132. The other end of the inductor 134i is electrically connected to the output terminal of the second amplifier 133. The other end of the inductor 134j is electrically connected to the output terminal 102 through the impedance matching unit 160, for example. Using such a lumped coupler as the combiner 134 can maintain low impedance in a low frequency range.

The control amplifier 140 is an amplifier that outputs a control signal S_{cont} for controlling the load impedance of the balanced amplifier circuit 130, for example. For example, the control amplifier 140 outputs the control signal S_{cont} by amplifying the signal RF12 adjusted by the first power splitter 120 based on the characteristics of the signal RF1. The control amplifier 140 is biased to class AB, for example.

In the power amplifier module 100, as described above, the amplifiers included in the balanced amplifier circuit 130 and the control amplifier 140 are formed of class AB amplifiers having the same operating point, thus facilitating designing.

The impedance matching unit 150 includes a transmission line transformer and converts impedance at a predetermined conversion ratio (here, “12:1” as an example). The impedance matching unit 150 is electrically connected between the control amplifier 140 and the balanced amplifier circuit 130. The impedance matching unit 150 matches the load impedance of the control amplifier 140 and the input impedance of the combiner 134 of the balanced amplifier circuit 130. The power amplifier module 100 can widen the band by using such a transmission line transformer to form a circuit for impedance matching.

As shown in FIG. 1, the transmission line

transformer of the impedance matching unit 150 includes a main line L1 and a sub line L2, for example. The transmission line transformer may be formed, for example, on the surface of each layer of a multilayer substrate or may be configured so that the main line L1 and the sub line L2 overlap in a stacking direction. A control signal S_{cont} outputted from the control amplifier 140 may be supplied to one end of the main line L1. A power supply Vcc may be supplied to one end of the sub line L2. In other words, the power supply Vcc may be electrically connected to one end of the sub line L2 of the transmission line transformer of the impedance matching unit 150. The other end of the sub line L2 is electrically connected to the other end of the main line L1. Specifically, the impedance matching unit 150 outputs the converted control signal S_{cont} from the other end of the main line L1 by impedance conversion using electromagnetic coupling energy from the sub line L2 to the main line L1.

The impedance matching unit 160 includes a transmission line transformer and converts impedance at a predetermined conversion ratio (here, “1:14” as an example). The impedance matching unit 160 is electrically connected between the balanced amplifier circuit 130 and the output terminal 102. The impedance matching unit 160 matches the load impedance of the combiner 134 of the balanced amplifier circuit 130 and the load impedance. The power amplifier module 100 can widen the band by using such a transmission line transformer to form a circuit for impedance matching.

As shown in FIG. 1, the transmission line transformer of the impedance matching unit 160 includes a main line L3 and a sub line L4, for example. The transmission line transformer may be formed, for example, on the surface of each layer of a multilayer substrate or may be configured so that the main line L3 and the sub line L4 overlap in the vertical direction. An output signal outputted from the balanced amplifier circuit 130 may be supplied to one end of the main line L3. A power supply Vcc may be supplied to one end of the sub line L4. In other words, the power supply Vcc may be electrically connected to one end of the sub line L4 of the transmission line transformer of the impedance matching unit 160. The other end of the sub line L4 is electrically connected to the other end of the main line L3. Specifically, the impedance matching unit 160 outputs the converted output signal from the other end of the main line L3 by impedance conversion using electromagnetic coupling energy from the sub line L4 to the main line L3.

As described above, in the power amplifier module 100, the power supply Vcc may be connected to one end of the sub line (for example, the sub line L2 and the sub-line L4) of the transmission line transformer. This allows the transmission line transformer to have an impedance conversion function and also to function as a power supply line, thus leading to reduction in size of the power amplifier module 100.

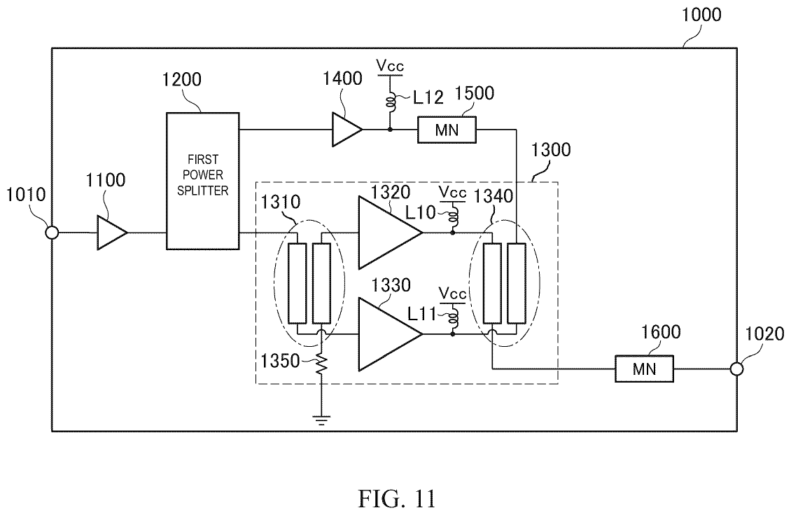

With reference to FIG. 11, a description will be given of the reduction in size of the power amplifier module 100 compared to a power amplifier module 1000 according to a comparative example. FIG. 11 is a diagram showing an example of a configuration of the power amplifier module 1000 according to the comparative example. As shown in FIG. 11, in the power amplifier module 1000 according to the comparative example, a matching circuit 1500 (not connected to a power supply Vcc) is provided at an output terminal of a control amplifier 1400, and a matching circuit 1600 (not connected to the power supply Vcc) is also provided between a balanced amplifier circuit 1300 and an output terminal 1020. In the power amplifier module 1000, a first amplifier 1320, a second amplifier 1330, and the control amplifier 1400 are electrically connected to the power supply Vcc through inductors L10, L11, and L12, respectively.

In the power amplifier module 100, on the other hand, the transmission line transformer of the impedance matching unit 150 functions as a matching circuit for impedance matching between the control amplifier 140 and the combiner 134, and also functions as a wiring for electrically connecting each of the second amplifier 133 and the control amplifier 140 to the power supply Vcc. In the power amplifier module 100, the transmission line transformer of the impedance matching unit 160 functions as a matching circuit for impedance matching between the balanced amplifier circuit 130 and the output terminal 102 (load impedance), and also functions as a wiring for electrically connecting the first amplifier 132 to the power supply Vcc. This allows the power amplifier module 100 to have fewer components than the power amplifier module 1000 and thus to be reduced in size.

The power amplifier module 100 may also have some of its components formed on-chip (for example, a silicon semiconductor chip or a III-V compound semiconductor chip). Specifically, the power amplifier module 100 may have, for example, the drive amplifier 110, the first power splitter 120, the balanced amplifier circuit 130, the control amplifier 140, and the impedance matching unit 150 formed on-chip. This can prevent the generation of parasitic inductance that is optional for the outputs of the balanced amplifier circuit 130 and the control amplifier 140, thereby maintaining the characteristics of the power amplifier module 100. Note that when the signal RFin is in a high frequency range such as a 6 GHz band, for example, the impedance matching unit 160 may also be formed on-chip. This can prevent deviation in impedance matching due to parasitic inductance in the impedance matching unit 160. In this embodiment, a circuit including components formed on-chip, for example, may also be referred to as a “power amplifier circuit”.

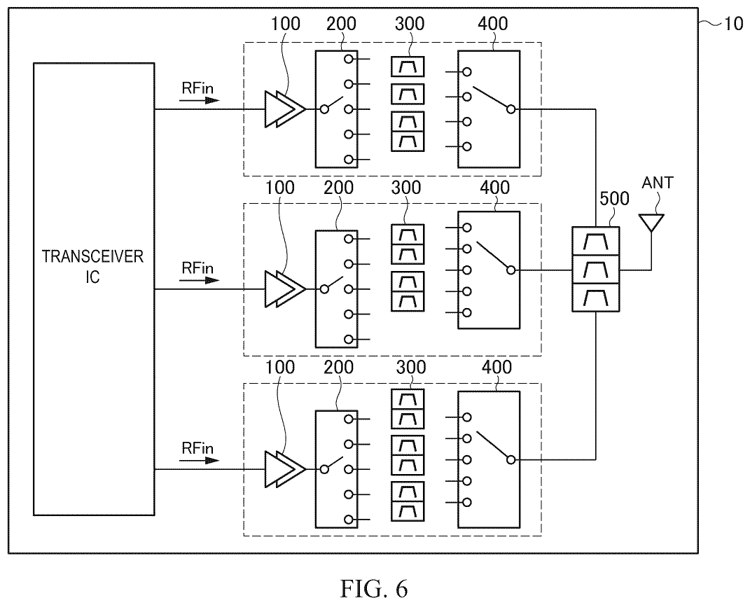

Next, with reference to FIG. 6, a configuration of a communication device 10 including the power amplifier module 100 will be described. FIG. 6 is a diagram showing an example of the configuration of the communication device 10 including the power amplifier module 100. As shown in FIG. 6, the communication device 10 includes, for example, the power amplifier module 100, a switch 200, a filter circuit 300, a switch 400, and a multiplexer 500.

The switches 200 and 400 include an input terminal and a plurality of output terminals, for example. The switches 200 and 400 may be, for example, matrix switches capable of electrically connecting each of a plurality of input terminals to at least one of a plurality of output terminals.

The filter circuit 300 is, for example, a circuit that attenuates signals in a predetermined frequency band. The filter circuit 300 may be, for example, a low pass filter, a band pass filter, a band elimination filter, a high pass filter, or the like.

The multiplexer 500 is, for example, a filter circuit that sorts an output signal RFout in a predetermined frequency band outputted from the power amplifier module 100 and a signal in a predetermined frequency band received by an antenna ANT.

### Operation of Power Amplifier Module 100

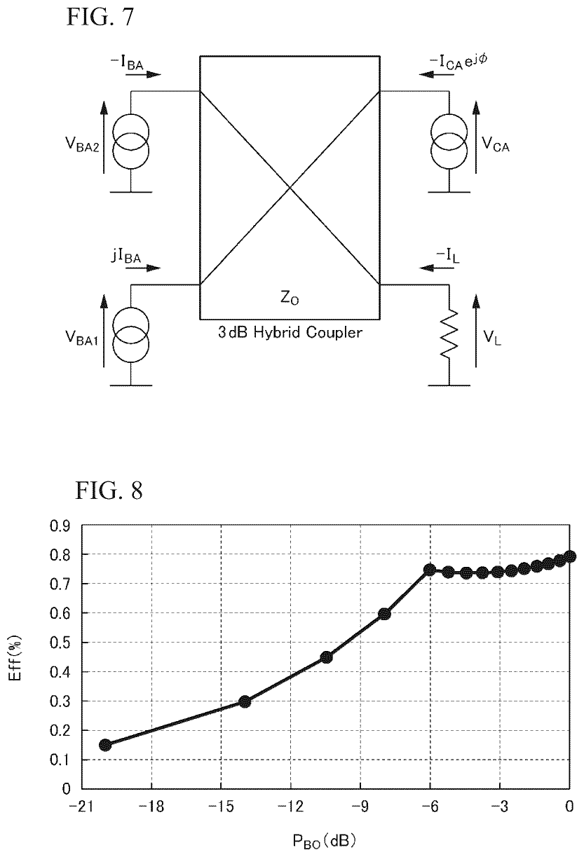

Next, the operation of the power amplifier module 100 will be described with reference to FIGS. 1 and 7. FIG. 7 is a diagram showing an example of a current inputted to the combiner 134.

As shown in FIG. 1, a signal RFin is inputted to the drive amplifier 110 through an input terminal 101. The drive amplifier 110 amplifies the signal RFin and outputs a signal RF1 to the first power splitter 120. The first power splitter 120 splits the signal RF1 into a signal RF11 to be outputted to the balanced amplifier circuit 130 and a signal RF12 to be outputted to the control amplifier 140. The first power splitter 120 may output the signal RF12 adjusted based on the characteristics of the signal RF1, for example, to the control amplifier 140.

Note that the control signal S_{cont} may be generated such that its power level decreases as the power level of the output signal RFout outputted from the power amplifier module 100 increases. In the power amplifier module 100, the load impedance of the balanced amplifier circuit 130 may be dynamically adjusted according to the power level of the output signal RFout by inputting such a control signal S_{cont} to the balanced amplifier circuit 130.

The control amplifier 140 amplifies the signal RF12 and outputs a control signal S_{cont}. The control signal S_{cont} is then inputted to the balanced amplifier circuit 130 through the impedance matching unit 150. The impedance matching unit 150 (for example, conversion ratio “12:1”) matches the load impedance (for example, “42.0 Ω”) of the control amplifier 140 with the impedance (for example, 3.5 Ω) of the impedance matching unit 160 of the balanced amplifier circuit 130 to be described later.

In the balanced amplifier circuit 130, the second power splitter 131 splits the signal RF11 into a signal RF11a to be outputted to the first amplifier 132 and a signal RF11b to be outputted to the second amplifier 133. The first amplifier 132 amplifies the signal RF11a and outputs the amplified signal. The second amplifier 133 amplifies the signal RF11b and outputs the amplified signal. The combiner 134 combines the amplified signals amplified by the first amplifier 132 and the second amplifier 133. In this event, a control signal S_{cont} is inputted to the combiner 134 to adjust the load impedance of the balanced amplifier circuit 130.

Here, with reference to FIG. 7, a description will be given of the operation where the balanced amplifier circuit 130 and the control amplifier 140 interact to adjust the load impedance of the balanced amplifier circuit 130 in the power amplifier module 100. In the power amplifier module 100, the load impedance of the balanced amplifier circuit 130 is adjusted by inputting a signal (hereinafter referred to as a “control signal S_{cont}”) outputted from the control amplifier 140 to the balanced amplifier circuit 130. The combiner 134 shown in FIG. 7 is, for example, a 3 dB hybrid coupler. In FIG. 7, for example, V_{L} represents the load impedance, V_{CA} represents the output voltage of the control amplifier 140, V_{BA1} represents the output voltage of the second amplifier 133, and V_{BA2} represents the output voltage of the first amplifier 132. Also, I_{CA} represents a current supplied from the control amplifier 140, eⱼφ represents the phase of I_{CA}, I_{BA} represents a current supplied from the first amplifier 132, jI_{BA} represents a current supplied from the second amplifier 133, and Z₀ represents characteristic impedance of the combiner 134. In the circuit shown in FIG. 7, the determinant of Formula (1), for example, holds true. Solving Formula (1) provides the relationship represented by Formula (2), for example. As shown in Formula (2), in the power amplifier module 100, the load impedances Z_{BA1} and Z_{BA2} of the balanced amplifier circuit 130 are adjusted by adjusting the amplitude and phase of the control signal S_{cont} outputted from the control amplifier 140.

$$\begin{matrix}[ Math 1 ] & \\ ( \begin{matrix}{V}_{L} \\ {V}_{BA 1} \\ {V}_{CA} \\ {V}_{BA 2}\end{matrix} ) = {Z}_{O} ( \begin{matrix}0 & 0 & - j & - j \sqrt{2} \\ 0 & 0 & - j \sqrt{2} & - j \\ - j & - j \sqrt{2} & 0 & 0 \\ - j \sqrt{2} & - j & 0 & 0\end{matrix} ) ( \begin{matrix}- {I}_{L} \\ {jI}_{BA} \\ - {I}_{CA} \text{?} \\ - {I}_{BA}\end{matrix} ) & ( 1 )\end{matrix}$$

$$\begin{matrix}[ Math 2 ] & \\ {Z}_{BA 1} = {Z}_{BA 2} = {Z}_{O} ( 1 + \sqrt{2} \frac{{I}_{CA}}{{I}_{BA}} \text{?} ) & ( 2 )\end{matrix}$$

$$\text{?} \text{indicates text missing or illegible when filed}$$

In Formula (2), Z_{BA1} represents the load impedance of the first amplifier 132 in the balanced amplifier circuit 130. Z_{BA2} represents the load impedance of the second amplifier 133 in the balanced amplifier circuit 130. Z₀ represents the characteristic impedance of the combiner 134, which is equal to the load impedance of the control amplifier 140.

Specifically, the power amplifier module 100 can adjust the load impedance, in a state where the load impedances of the first amplifier 132 and the second amplifier 133 are equal in the balanced amplifier circuit 130, by adjusting the amplitude and phase of the current I_{CA}. In other words, the power amplifier module 100 can adjust the load impedance of the balanced amplifier circuit 130 by inputting the control signal S_{cont} from outside to the balanced amplifier circuit 130. The load impedance of the balanced amplifier circuit 130 can thus be controlled so as to maintain high efficiency during back-off of the power amplifier module 100.

### Modification of Power Amplifier Module 100

### First Modification

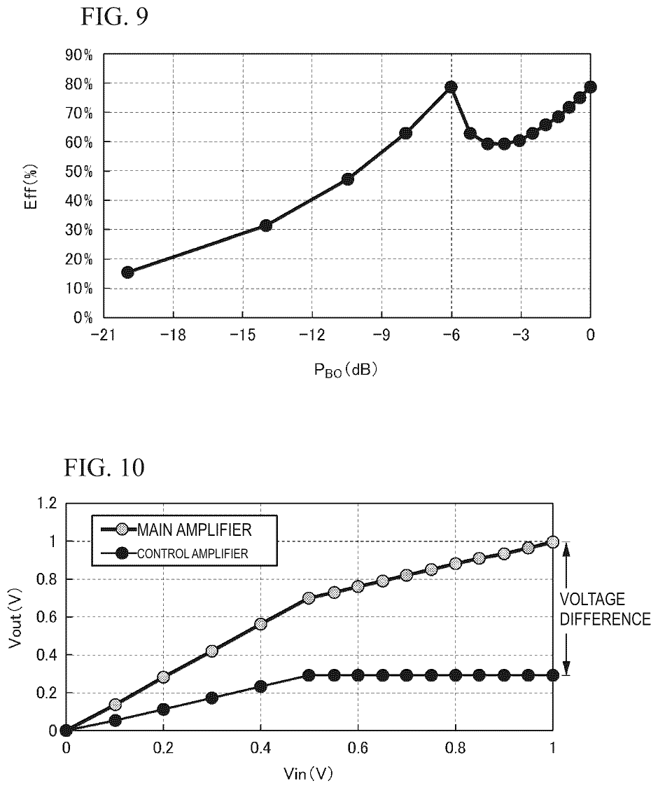

A modification of the power amplifier module 100 will be described with reference to FIGS. 8 and 9. FIGS. 8 and 9 are graphs each showing an example of the relationship between input power and efficiency of the power amplifier module 100 according to the modification. In FIGS. 8 and 9, the horizontal axis represents a power ratio P_{BO} of the balanced amplifier circuit 130 and the vertical axis represents output efficiency E_{ff}.

In the above description, the first amplifier 132, the second amplifier 133, and the control amplifier 140 are biased to class AB. In the power amplifier module 100 according to the modification, on the other hand, the first amplifier 132 and the second amplifier 133 may be biased to class AB and the control amplifier 140 may be biased to class C. This allows the control amplifier 140 to start up when the first amplifier 132 and the second amplifier 133 biased to class AB are saturated, thus improving the efficiency. Specifically, as shown in FIG. 8, the efficiency can be maintained by operating the control amplifier 140 when the power ratio P_{BO} is −6 dB. This configuration can also reduce the conversion ratio of the transmission line transformers of the impedance matching unit 150 and the impedance matching unit 160. This allows the impedance matching unit 150 and the impedance matching unit 160 to become smaller in size as the band becomes wider.

In the power amplifier module 100 according to the modification, the control amplifier 140 may be biased to class AB, and the first amplifier 132 and the second amplifier 133 may be biased to class C. This allows the first amplifier 132 and the second amplifier 133 to start up when the control amplifier 140 is saturated, thus maintaining the efficiency. Specifically, as shown in FIG. 9, the efficiency can be maintained by operating the first amplifier 132 and the second amplifier 133 when the power ratio P_{BO} is −6 dB.

### Second Modification

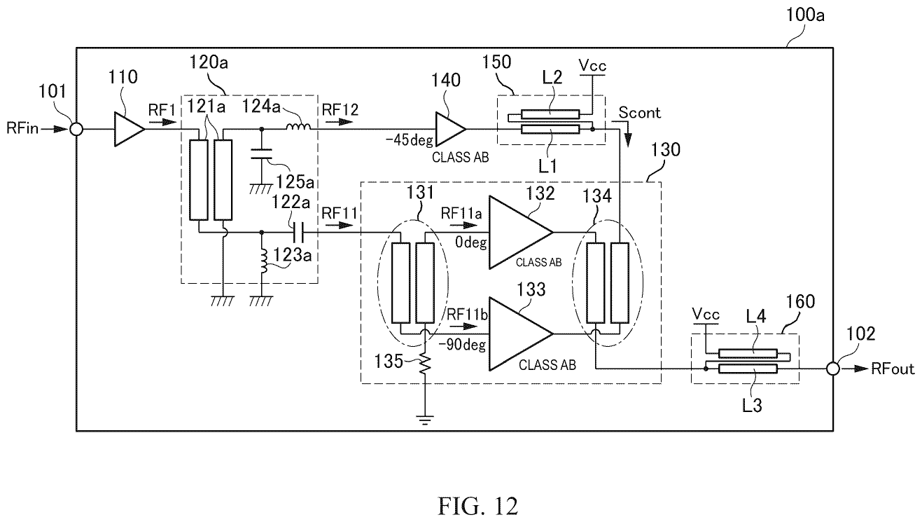

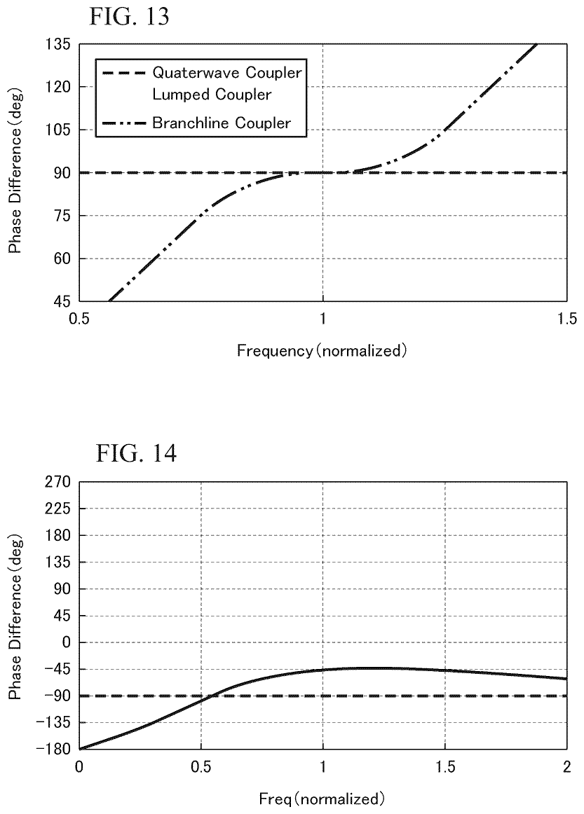

A power amplifier module 100a according to a second modification will be described with reference to FIGS. 12, 13, and 14. FIG. 12 is a diagram showing a configuration example of the power amplifier module 100a according to the second modification. FIG. 13 is a graph showing frequency characteristics of a parallel plate coupler. In FIG. 13, the horizontal axis represents a normalized frequency and the vertical axis represents a phase difference between two signals. FIG. 14 is a graph showing the relationship between a phase of a signal inputted to a control amplifier 140 and a phase of a signal inputted to a second amplifier 133 in the power amplifier module 100a according to the second modification. In FIG. 14, the horizontal axis represents a normalized frequency and the vertical axis represents a phase difference between two signals.

As shown in FIG. 12, in the power amplifier module 100a, a first amplifier 132 and a second amplifier 133 are biased to class AB, and the control amplifier 140 is biased to class AB. Compared to the power amplifier module 100, a first power splitter 120a in the power amplifier module 100a includes a splitter 121a, a capacitor 122a, an inductor 123a, an inductor 124a, and a capacitor 125a. In the power amplifier module 100a, a combiner 134 is formed of a parallel plate coupler. Note that a second power splitter 131 in the power amplifier module 100a can be formed of a parallel plate coupler. Note that the term “flat plates” facing each other to form the parallel plate coupler (for example, one flat plate 134a and the other flat plate 134b facing parallel to the flat plate 134a shown in FIG. 2) refers to a plate in which the area of a main surface facing the other flat plate is larger than the area of a side surface not facing the other flat plate.

The splitter 121a splits the signal RF1 into a signal RF11 (first input signal) and a signal RF12 (second input signal). The splitter 121a is formed of a parallel plate coupler formed by a pair of flat plates disposed facing parallel to each other. The splitter 121a may be a λ/4 line coupler but can be a parallel plate coupler from the viewpoint of miniaturization.

The capacitor 122a is connected in series to one flat plate of the splitter 121a and passes the signal RF11 to the second power splitter 131. The inductor 123a is shunt connected to the one flat plate. In other words, the inductor 123a is connected in series between the one flat plate and the reference potential.

The inductor 124a is connected in series to the other flat plate of the splitter 121a and passes the signal RF12 to the control amplifier 140. The capacitor 125a is shunt connected to the other flat plate. In other words, the capacitor 125a is connected in series between the other flat plate and the reference potential.

As shown in FIG. 13, the parallel plate coupler can split a signal into two signals with a phase difference of approximately 90 degrees regardless of frequency. As can be seen from FIG. 13, the parallel plate coupler (dashed line) has better frequency characteristics than a branch line coupler (two-dot chain line).

Specifically, in the power amplifier module 100a, the two split signals whose phases are adjusted by the parallel plate coupler, capacitors, and inductors are combined by the parallel plate coupler of the combiner 134. As shown in FIG. 14, the power amplifier module 100a can thus adjust the phase difference between the signal (RF12) inputted to the control amplifier 140 and the signal (RF11a) inputted to the second amplifier 133 to be around 45 degrees (solid line), for example, so that the load impedance of the balanced amplifier circuit 130 is optimally controlled, with respect to the phase difference of 90 degrees (dashed line) between the signals (RF11a and RF11b) inputted to the second amplifier 133.

As shown in Formula (2), the power amplifier module 100a can thus optimally control the load impedance of the balanced amplifier circuit 130 by adjusting the phase of the current I_{CA}.

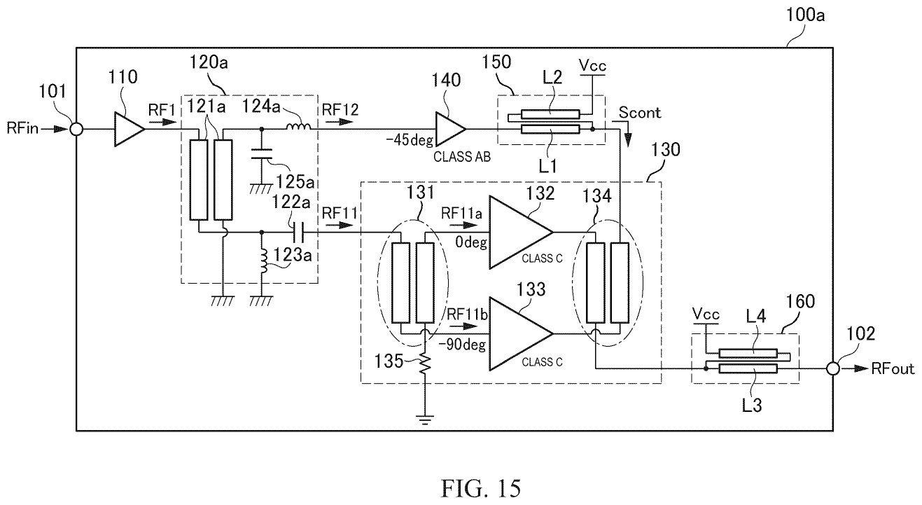

Here, with reference to FIG. 15, another modification of the power amplifier module 100a according to the second modification will be described. FIG. 15 is a diagram showing a modification of the power amplifier module 100a according to the second modification.

As shown in FIG. 15, the power amplifier module 100a can similarly obtain the frequency characteristics shown in FIG. 14 even when the first amplifier 132 and the second amplifier 133 are biased to class C, and can thus control the load impedance of the balanced amplifier circuit 130. The power amplifier module 100a can therefore improve the output efficiency by widening the band.

### Third Modification

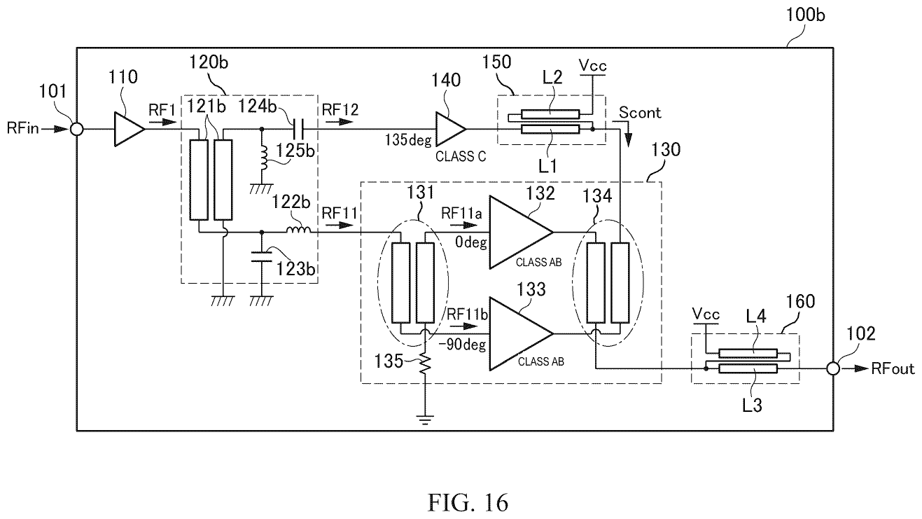

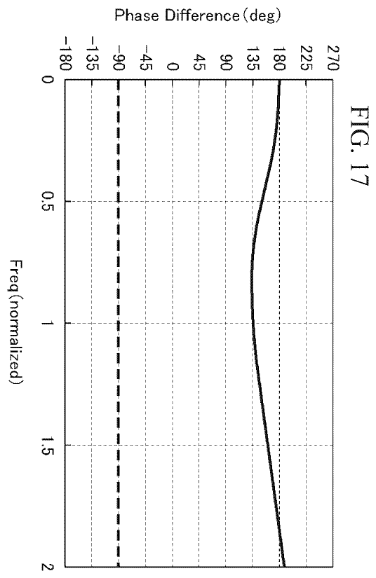

A power amplifier module 100b according to a third modification will be described with reference to FIGS. 16 and 17. FIG. 16 is a diagram showing a configuration example of the power amplifier module 100b according to the third modification. FIG. 17 is a graph showing the relationship between a phase of a signal inputted to a control amplifier 140 and a phase of a signal inputted to a second amplifier 133 in the power amplifier module 100b according to the third modification. In FIG. 17, the horizontal axis represents a normalized frequency and the vertical axis represents a phase difference between the two signals.

As shown in FIG. 16, the control amplifier 140 in the power amplifier module 100b is biased to class C, unlike the power amplifier module 100a according to the second modification. A first power splitter 120b in the power amplifier module 100b includes a splitter 121b, an inductor 122b, a capacitor 123b, a capacitor 124b, and an inductor 125b. In the power amplifier module 100b, a combiner 134 is formed of a parallel plate coupler. Note that a second power splitter 131 in the power amplifier module 100b can be formed of a parallel plate coupler.

The splitter 121b is the same as the splitter 121a, and thus description thereof will be omitted.

The inductor 122b is connected in series to one flat plate of the splitter 121b and passes a signal RF11 to the second power splitter 131. The capacitor 123b is shunt connected to the one flat plate. In other words, the capacitor 123b is connected in series between the one flat plate and the reference potential.

The capacitor 124b is connected in series to the other flat plate of the splitter 121b and passes a signal RF12 to the control amplifier 140. The inductor 125b is shunt connected to the other flat plate. In other words, the inductor 125b is connected in series between the other flat plate and the reference potential.

In the power amplifier module 100b, two split signals whose phases are adjusted by the parallel plate coupler, capacitors, and inductors are combined by the parallel plate coupler of the combiner 134. As shown in FIG. 17, the power amplifier module 100b can thus adjust the phase difference between the signal (RF12) inputted to the control amplifier 140 and the signal (RF11a) inputted to the second amplifier 133 to be around 135 degrees (solid line), for example, so that the load impedance of the balanced amplifier circuit 130 is optimally controlled, with respect to the phase difference of 90 degrees (dashed line) between the signals (RF11a and RF11b) inputted to the second amplifier 133.

As shown in Formula (2), the power amplifier module 100b can thus optimally control the load impedance of the balanced amplifier circuit 130 by adjusting the phase of the current I_{CA}. The power amplifier module 100b can therefore improve the output efficiency by widening the band.

### SUMMARY

Hereinafter, as an example, it will be explicitly stated that in the power amplifier module 100, the signal RF11 corresponds to a “first input signal” in the claims, and the signal RF12 corresponds to a “second input signal” in the claims. The balanced amplifier circuit 130 corresponds to an “amplifier circuit” in the claims, and the first amplifier 132 and the second amplifier 133 correspond to a “pair of amplifiers” in the claims. The main line L1 corresponds to a “first main line” in the claims, and the sub line L2 corresponds to a “first sub line” in the claims. The impedance matching unit 150 corresponds to a “first impedance matching unit” in the claims, and the impedance matching unit 160 corresponds to a “second impedance matching unit” in the claims. The main line L3 corresponds to a “second main line” in the claims, and the sub line L4 corresponds to a “second sub line” in the claims. The signal RF11a corresponds to a “first signal” in the claims, and the signal RF11b corresponds to a “second signal” in the claims.

The power amplifier module 100 according to the exemplary embodiment of the present disclosure includes: the first power splitter 120 that splits an input signal (here, a signal RF1) into the signal RF11 and the signal RF12; the balanced amplifier circuit 130 that includes a pair of first amplifier 132 and second amplifier 133 electrically connected in parallel and that amplifies the signal RF11 and outputs the output signal RFout to the output terminal 102; the control amplifier 140 that amplifies the signal RF12 and outputs, to the balanced amplifier circuit 130, the control signal S_{cont} for controlling the load impedance of the balanced amplifier circuit 130; and the impedance matching unit 150 electrically connected in series between the balanced amplifier circuit 130 and the control amplifier 140. The impedance matching unit 150 includes a transmission line transformer. With this configuration, the power amplifier module 100 can improve output efficiency by widening a band.

The transmission line transformer of the impedance matching unit 150 in the power amplifier module 100 includes a main line L1 and a sub line L2. The main line L1 is electrically connected in series between the balanced amplifier circuit 130 and the control amplifier 140. The sub line L2 has one end portion electrically connected to one end portion of the main line L1 and the other end portion electrically connected to a power supply Vcc. This configuration eliminates the need to provide wiring (inductors) between the power supply Vcc and each amplifier, besides the transmission line transformer for impedance matching. The power amplifier module 100 is thus reduced in size.

The power amplifier module 100 further includes the impedance matching unit 160 electrically connected in series between the balanced amplifier circuit 130 and the output terminal 102. The impedance matching unit 160 includes a transmission line transformer. This makes it possible to widen the band and improve the output efficiency.

The transmission line transformer of the impedance matching unit 160 in the power amplifier module 100 includes the main line L3 and the sub line L4. The main line L3 is electrically connected in series between the balanced amplifier circuit 130 and the output terminal 102. The sub line L4 has one end portion electrically connected to one end portion of the main line L3 and the other end portion electrically connected to the power supply Vcc. This configuration eliminates the need to provide wiring (inductors) between the power supply Vcc and each amplifier, besides the transmission line transformer for impedance matching. The power amplifier module 100 is thus reduced in size.

The pair of first amplifier 132 and second amplifier 133 of the power amplifier module 100 are amplifiers of the same class as the amplifier operating point of the control amplifier 140. This facilitates the design of the power amplifier module 100.

The pair of first amplifier 132 and second amplifier 133 of the power amplifier module 100 are amplifiers that operate in class AB, and the control amplifier 140 is an amplifier that operates in class AB. This allows the power amplifier module 100 to widen the band.

The pair of first amplifier 132 and second amplifier 133 of the power amplifier module 100 are amplifiers of a different class from the amplifier operating point of the control amplifier 140. This allows the power amplifier module 100 to widen the band.

The pair of first amplifier 132 and second amplifier 133 of the power amplifier module 100 are amplifiers that operate in class AB, and the control amplifier 140 is an amplifier that operates in class C. This allows the power amplifier module 100 to widen the band.

The balanced amplifier circuit 130 of the power amplifier module 100 includes: the second power splitter 131 that splits the signal RF11 into the signal RF11a and the signal RF11b; the first amplifier 132 that amplifies the signal RF11a split by the second power splitter 131, and outputs a first output signal; the second amplifier 133 that amplifies the signal RF11b split by the second power splitter 131 (second power splitter), and outputs a second output signal; and the combiner 134 that combines the first output signal and the second output signal to output the output signal RFout. The control signal S_{cont} is inputted to the combiner 134 to control the load impedance of the balanced amplifier circuit 130. This allows the power amplifier module 100 to widen the band.

The combiner 134 (combiner) of the power amplifier module 100 is formed of a parallel plate coupler formed of a pair of flat plates disposed facing parallel to each other. This allows the power amplifier module 100 to be reduced in size.

The combiner 134 (combiner) of the power amplifier module 100 is formed of a λ/4 line coupler formed by wiring having a line length that is one-fourth of the wavelength at the frequency of the input signal. This allows low impedance to be maintained across a wide band.

The combiner 134 (combiner) of the power amplifier module 100 is formed of a branch line coupler. This allows low impedance to be maintained at high frequencies such as millimeter waves.

The first power splitter 120, the balanced amplifier circuit 130, the control amplifier 140, and the impedance matching unit 150 of the power amplifier module 100 are formed on the same chip. This can prevent deviation in impedance matching due to parasitic inductance in the impedance matching unit 160 in the power amplifier module 100.

In the power amplifier module 100a, the first power splitter 120a includes: the splitter 121a configured to split the signal RF1 (input signal) into the signal RF11 (first input signal) and the signal RF12 (second input signal) and formed of a parallel plate coupler formed of a pair of flat plates disposed facing parallel to each other; the capacitor 122a (first capacitor) that is connected in series to one flat plate of the splitter 121a and passes the signal RF11 (first input signal) to the balanced amplifier circuit 130 (amplifier circuit); the inductor 123a (first inductor) that is shunt connected to the one flat plate; the inductor 124 (second inductor) that is connected in series to the other flat plate of the splitter 121a and passes the signal RF12 (second input signal) to the control amplifier 140 (biased to class AB); and the capacitor 125a (second capacitor) that is shunt connected to the other flat plate. The balanced amplifier circuit 130 (amplifier circuit) includes: the second power splitter 131 that splits the signal RF11 (first input signal) into the signal RF11a (first signal) and the signal RF11b (second signal); a pair of amplifiers including the first amplifier 132 that amplifies the signal RF11a (first signal) split by the second power splitter 131 and outputs a first output signal and the second amplifier 133 that amplifies the signal RF11b (second signal) split by the second power splitter 131 and outputs a second output signal; and the combiner 134 that combines the first output signal and the second output signal to output the output signal RFout, and that is formed of a parallel plate coupler formed of a pair of flat plates disposed facing parallel to each other. The control signal S_{cont} is inputted to the combiner 134 to control the load impedance of the balanced amplifier circuit 130 (amplifier circuit). This makes it possible to widen the band and improve the output efficiency.

In the power amplifier module 100b, the first power splitter 120b includes: the splitter 121b configured to split the signal RF1 (input signal) into the signal RF11 (first input signal) and the signal RF12 (second input signal) and formed of a parallel plate coupler formed of a pair of flat plates disposed facing parallel to each other; an inductor 122b (third inductor) that is connected in series to one flat plate of the splitter 121b and passes the signal RF11 (first input signal) to the balanced amplifier circuit 130 (amplifier circuit); the capacitor 123b (third capacitor) that is shunt connected to the one flat plate; the capacitor 124b (fourth capacitor) that is connected in series to the other flat plate of the splitter 121b and passes the signal RF12 (second input signal) to the control amplifier 140 (biased to class C); and the inductor 125b (fourth inductor) that is shunt connected to the other flat plate. The balanced amplifier circuit 130 (amplifier circuit) includes: the second power splitter 131 that splits the signal RF11 (first input signal) into the signal RF11a (first signal) and the signal RF11b (second signal); a pair of amplifiers including the first amplifier 132 that amplifies the signal RF11a (first signal) split by the second power splitter 131 and outputs a first output signal and the second amplifier 133 that amplifies the signal RF11b (second signal) split by the second power splitter 131 and outputs a second output signal; and the combiner 134 that combines the first output signal and the second output signal to output the output signal RFout, and that is formed of a parallel plate coupler formed of a pair of flat plates disposed facing parallel to each other. The control signal S_{cont} is inputted to the combiner 134 to control the load impedance of the balanced amplifier circuit 130 (amplifier circuit). This makes it possible to widen the band and improve the output efficiency.

The foregoing embodiments are provided to facilitate understanding of the present disclosure and are not intended to limit the scope of the present disclosure. Changes or improvements may be made to the present disclosure without necessarily departing from the scope of the present disclosure, and the present disclosure also includes equivalents thereof. That is, design changes may be made to the embodiments in an appropriate manner by those skilled in the art, and such embodiments are also within the scope of the present disclosure as long as they have features of the present disclosure. The elements included in the embodiments, the arrangement thereof, and the like are not limited to those described above as examples, and may be changed as appropriate.

### REFERENCE SIGNS LIST

100, 100a, 100b POWER AMPLIFIER MODULE
110 DRIVE AMPLIFIER
120, 120a, 120b FIRST POWER SPLITTER
130 BALANCED AMPLIFIER CIRCUIT
131 SECOND POWER SPLITTER
132 FIRST AMPLIFIER
133 SECOND AMPLIFIER
134 COMBINER
140 CONTROL AMPLIFIER
150 IMPEDANCE MATCHING UNIT
160 IMPEDANCE MATCHING UNIT

1. A power amplifier circuit comprising:
a first power splitter that is configured to split an input signal into a first input signal and a second input signal;
an amplifier circuit that comprises a pair of amplifiers electrically connected in parallel, and that is configured to amplify the first input signal and to output an output signal to an output terminal;
a control amplifier that is configured to amplify the second input signal and to output, to the amplifier circuit, a control signal that controls a load impedance of the amplifier circuit; and
a first impedance matching circuit electrically connected in series between the amplifier circuit and the control amplifier,
wherein the first impedance matching circuit comprises a transmission line transformer.

2. The power amplifier circuit according to claim 1,
wherein the transmission line transformer of the first impedance matching circuit comprises a first main line and a first sub line,
wherein the first main line is electrically connected in series between the amplifier circuit and the control amplifier, and
wherein the first sub line has a first end electrically connected to a first end of the first main line, and a second end electrically connected to a power supply.

3. The power amplifier circuit according to claim 1, further comprising:
a second impedance matching circuit electrically connected in series between the amplifier circuit and the output terminal,
wherein the second impedance matching circuit comprises a transmission line transformer.

4. The power amplifier circuit according to claim 3,
wherein the transmission line transformer of the second impedance matching circuit comprises a second main line and a second sub line,
wherein the second main line is electrically connected in series between the amplifier circuit and the output terminal, and
wherein the second sub line has a first end electrically connected to a first end of the second main line, and a second end electrically connected to a power supply.

5. The power amplifier circuit according to claim 1, wherein the pair of amplifiers are amplifiers of the same class as an operating point of the control amplifier.

6. The power amplifier circuit according to claim 5, wherein the pair of amplifiers operate in class AB, and the control amplifier operates in class AB.

7. The power amplifier circuit according to claim 1, wherein the pair of amplifiers are amplifiers of a class different from an operating point of the control amplifier.

8. The power amplifier circuit according to claim 7, wherein the pair of amplifiers operate in class AB, and the control amplifier operates in class C.

9. The power amplifier circuit according to claim 1,
wherein the amplifier circuit further comprises a second power splitter configured to split the first input signal into a first signal and a second signal,
wherein the pair of amplifiers comprises a first amplifier that is configured to amplify the first signal and to output a first output signal, and a second amplifier that is configured to amplify the second signal and to output a second output signal,
wherein the amplifier circuit further comprises a combiner that is configured to combine the first output signal and the second output signal, and to output the output signal, and
wherein the control signal is inputted to the combiner and controls the load impedance of the amplifier circuit.

10. The power amplifier circuit according to claim 9, wherein the combiner comprises a parallel plate coupler having a pair of flat plates that are parallel to each other.

11. The power amplifier circuit according to claim 9, wherein the combiner comprises a λ/4 line coupler having a wiring with a line length that is one-fourth of a wavelength of a frequency of the input signal.

12. The power amplifier circuit according to claim 9, wherein the combiner comprises a branch line coupler.

13. A power amplifier module comprising the power amplifier circuit according to claim 1, wherein the first power splitter, the amplifier circuit, the control amplifier, and the first impedance matching circuit are on the same chip.

14. The power amplifier circuit according to claim 6, wherein the first power splitter comprises:
a splitter configured to split the input signal into the first input signal and the second input signal, and comprises a first parallel plate coupler having a first pair of flat plates that are parallel to each other,
a first capacitor that is connected in series to a first of the first pair of flat plates of the splitter and that is configured to pass the first input signal to the amplifier circuit,
a first inductor that is shunt connected to the first flat plate,
a second inductor that is connected in series to a second of the first pair of flat plates of the splitter and that is configured to pass the second input signal to the control amplifier, and
a second capacitor that is shunt connected to the second flat plate,
wherein the amplifier circuit further comprises a second power splitter that is configured to split the first input signal into a first signal and a second signal,
wherein the pair of amplifiers comprises a first amplifier that is configured to amplify the first signal and to output a first output signal, and a second amplifier that is configured to amplify the second signal and to output a second output signal,
wherein the amplifier circuit further comprises a combiner that is configured to combine the first output signal and the second output signal and to output the output signal, and that comprises a second parallel plate coupler having a second pair of flat plates that are parallel to each other, and
wherein the control signal is inputted to the combiner and controls the load impedance of the amplifier circuit.

15. The power amplifier circuit according to claim 8,
wherein the first power splitter comprises:
a splitter configured to split the input signal into the first input signal and the second input signal, and comprises a first parallel plate coupler having a first pair of flat plates that are parallel to each other,
a third inductor that is connected in series to a first of the first pair of flat plates of the splitter and that is configured to pass the first input signal to the amplifier circuit,
a third capacitor that is shunt connected to the first flat plate,
a fourth capacitor that is connected in series to a second of the first pair of flat plates of the splitter and that is configured to pass the second input signal to the control amplifier, and
a fourth inductor that is shunt connected to the second flat plate,
wherein the amplifier circuit further comprises a second power splitter that is configured to split the first input signal into a first signal and a second signal,
wherein the pair of amplifiers comprises a first amplifier that is configured to amplify the first signal and to output a first output signal, and a second amplifier that is configured to amplify the second signal and to output a second output signal,
wherein the amplifier circuit further comprises a combiner that is configured to combine the first output signal and the second output signal and to output the output signal, and that comprises a second parallel plate coupler having a second pair of flat plates that are parallel to each other, and
wherein the control signal is inputted to the combiner and controls the load impedance of the amplifier circuit.
